(19) United States
(12) Patent Application Publication
(10) Pub. No.: US 2026/0173433 A1
(43) Pub. Date: Jun. 18, 2026

(54) VERTICAL HEMT AND A METHOD TO PRODUCE A VERTICAL HEMT

(71) Applicant: Epinovatech AB, Lund (SE)

(72) Inventor: Martin Andreas Olsson, Lund (SE)

(21) Appl. No.: 19/532,855

(22) Filed: Feb. 6, 2026

Related U.S. Application Data
(63) Continuation of application No. 17/999,605, now Pat. No. 12,557,325.

(30) Foreign Application Priority Data
May 29, 2020 (EP) 20177453.6

(51) Int. Cl. H10D 30/47; H10D 30/01; H10D 62/10; H10D 62/85

(52) U.S. Cl. CPC H10D 30/477; H10D 30/014; H10D 30/015; H10D 62/114; H10D 62/122; H10D 62/8503

(57) ABSTRACT

There is provided a vertical high-electron-mobility transistor, HEMT (100), comprising: a drain contact (410), a nanowire layer (500) arranged on the drain contact (410) and comprising at least one vertical nanowire (510) and a supporting material (520) laterally enclosing the at least one vertical nanowire (510), a heterostructure (600) arranged on the nanowire layer and comprising an AlGaN-layer (610) and a GaN-layer (620) together forming a heterojunction, at least one source contact (420a, 420b) in contact with the heterostructure (600), and a gate contact (430) in contact with the heterostructure (600), arranged above the at least one vertical nanowire (510), wherein the at least one vertical nanowire (510) is forming an electron transport channel between the drain contact and the heterostructure. There is also provided a method for producing a vertical HEMT (100).

### TECHNICAL FIELD

The present invention relates to vertical high electron mobility transistors, HEMTs, and methods of producing such transistors. Specifically, the invention relates to vertical HEMTs, meaning that the main current flow is oriented vertically, or perpendicular, to the surface.

### BACKGROUND

A HEMT is a type of field-effect transistor comprising a heterojunction of materials with different band gaps, such as GaN and AlGaN. The orientation of a transistor can be lateral or vertical, meaning that the current flow between the source and the drain contacts of the transistor can be either perpendicular or parallel to the surface of the transistor or a substrate onto which the transistor is based. In a vertical HEMT, the drain contact can be placed at the bottom of the device, while the source contacts can be placed at the top. Transistor operation, i.e. if a current is conducted between the source and drain contacts or not, is controlled by application of a voltage to a gate contact. In more traditional horizontal HEMTs the currents mainly flow through the transistor in the horizontal direction, mediated through the so-called 2-dimensional electron gas, 2DEG, formed at the interface between the heterojunction of different band gap materials. In vertical HEMTs, as the name might suggest, the current flow also comprises a significant vertical component. The main vertically conducting portion of the vertical HEMT is often referred to as the aperture of vertical HEMTs. Vertical HEMTs in general enable improved area downscaling of transistors due to in part the possibilities of more effective use of the bottom/backside for contacts. However, in order to continue downscaling vertical HEMTs further improvements are required and new aspects of the HEMT need to be considered.

### SUMMARY OF THE INVENTION

An object of the present disclosure is to at least address the above concerns.

According to a first aspect there is provided a vertical high-electron-mobility transistor, HEMT. The vertical HEMT comprises a drain contact. The vertical HEMT comprises a nanowire layer. The nanowire layer is arranged on the drain contact. The nanowire layer comprises at least one vertical nanowire. The nanowire layer comprises a supporting material laterally enclosing the at least one vertical nanowire. The vertical HEMT comprises a heterostructure arranged on the nanowire layer. The heterostructure comprises an AlGaN-layer and a GaN-layer together forming a heterojunction. The vertical HEMT comprises at least one source contact in contact with the heterostructure. The vertical HEMT comprises a gate contact in contact with the heterostructure. The gate contact arranged above the at least one vertical nanowire. At least one vertical nanowire is forming an electron transport channel between the drain contact and the heterostructure.

A layer or structure being arranged on another layer or structure should be understood as the layer or structure being located substantially above the other layer or structure as seen from a side/cross sectional view of the device where the substrate is at the bottom of the view. The layer or structure may be directly in contact with the other layer or structure or otherwise, as long as it is substantially above. This should however not be construed as limiting the two layers or structures from vertically overlapping each other as seen from the same side/cross sectional view. Directional terms such as vertically and laterally should be understood in this same context.

The term heterostructure should be understood as a singular integral structure which consists of substantially two different structures with a clearly defined interface/transition between the two.

The inventor has realized that further scaling of vertical HEMTs may be made possible by utilizing vertical nanowire structure as a vertical HEMT aperture. By in an extreme case using just one nanowire as an electron transport channel, HEMTs of truly miniscule size may be created.

Vertical nanowires should furthermore be considered advantageous in a vertical HEMT due to their substantially 1-dimensional electron transport properties. This feature may be attributed to the material structure and the way that it is formed into a nanowire and should not be construed with a similar dimension structure of bulk material of same or similar elemental composition.

Nanowires may feature significantly fewer material defects compared to said bulk material further adding to the benefits of their incorporation. Less defects generally leads to improved electric conduction characteristics.

Vertical nanowires may also be less complex to produce than similar scale, high quality, aperture of bulk material due to the nanowires being substantially self-aligning during epitaxial formation.

Gallium nitride, GaN,-based semiconductors, i.e. compounds comprising (but not exclusively containing) gallium and nitrogen, provide numerous advantages compared to silicon. Electronic devices based thereon such as HEMTs and vertical HEMTs provide a promising candidate for replacing many silicon-based devices.

GaN-based HEMTs may offer faster switching speeds, increased electron mobility, lower resistances, larger breakdown voltages, etc. Compared to silicon-based transistors, a GaN-based device may offer low on-state resistances, and low switching losses when used as power switching transistors for voltage converter applications.

Further, GaN may exhibit ballistic transport at room temperature, especially if the GaN is in the form of a one-dimensional structure such as e.g. a nanowire. The ballistic transport may be attributed to GaN having a high optical phonon energy. The optical phonon energy of GaN may be around 4 times higher than the optical phonon energy of other III-V semiconductors. The ballistic transport and/or the high optical phonon energy may lead to a high electron mobility and a lower ON-resistance, Rds(on), which may be advantageous for power chips. Ballistic transport in GaN is discussed by Matioli et al. in “Room-temperature ballistic transport in III-nitride heterostructures”. Nano letters, (2015) 15(2), 1070-1075.

The at least one vertical nanowire may, at a first end thereof, be in direct contact with the drain contact and, at a second end thereof, be in direct contact with the heterostructure.

The material of the one vertical nanowire may be different from the supporting material.

Due to the material difference between the at least one vertical nanowire and the supporting material, a current blocking layer may be realized by the supporting material while an electron transport channel is established by the at least one vertical nanowire. This creates a possibility for in-situ growth and efficient manufacturing of the important features of the HEMT. The structure of the supporting layer enclosing the at least one nanowire may eliminate the need for cumbersome manufacturing methods such as ion-implantation.

The at least one vertical nanowire may comprise GaN.

GaN nanowires generally predictably form in the wurtzite crystal structure. GaN nanowires may form good 1-dimensional current tranport channels.

The at least one vertical nanowire may comprise n-doped GaN. The supporting material comprises p-doped GaN.

The nanowire layer may thus be formed with the at least one vertical nanowire and the supporting material having substantially the same lattice constants. In turn this may lead to less defects and improved structural integrity of the vertical HEMT. The different doped material may still make sure that the supporting layer acts as a current blocking layer around the at least one vertical nanowire.

The supporting material may be configured to be a current blocking layer.

The term current blocking layer should be understood as a layer that prevents the current to leave the electron transport channel. Having the supporting material act as a current blocking layer may reduce current leakage to/from the at least one vertical nanowire electron transport channel. In turn, this may lead to reduced transistor losses and higher efficiency operation.

The at least one vertical nanowire may be laterally aligned with the gate contact.

By laterally aligned, it should be understood that the at least one vertical nanowire at least overlaps the area of the gate contact when viewed from a top view.

The gate may form a 2DEG at the heterojunction interface from the source contact to the at least one vertical nanowire. For this it may be more efficient to place the gate laterally aligned with the gate contact.

The length of the at least one vertical nanowire may be in the range from 50 nm to 500 nm. The length may preferably be in the range from 150 nm to 250 nm.

Shorter vertical nanowires may correspond to thinner material overall and vice versa. Thinner material generally makes the vertical HEMT thinner and may require less material to produce. Thicker material aids to space the source and drain contacts further apart which may improve high voltage characteristics by reducing the risks of a breakdown current bypassing the at least one vertical nanowire and the heterojunction altogether.

In general, this may be an advantage of vertical HEMTs over horizontal HEMTs due the inherent isolation of the source and drain contacts compared to if both contacts are located on the same side of the device, laterally spaced in close proximity.

The nanowire layer may comprise a plurality of vertical nanowires.

Several additional vertical nanowires may be placed in parallel to the at least one vertical nanowire. More nanowires may provide options for modular device design. By adding more nanowires, the possible current density through the vertical HEMT may be proportionally increased in increments due to the increase in total aperture cross section area. Using a plurality of nanowires may be beneficial over using a single bulk material aperture of the same total cross section area due to the nanowires improved conductive properties.

The GaN-layer may be arranged on the AlGaN-layer.

The AlGaN-layer may alternatively be arranged on the GaN-layer as long as the two layer both form a common heterojunction.

According to a second aspect there is provided a method for producing a vertical HEMT. The method comprises providing a base layer wherein the base layer comprises a substrate. The method comprises forming a nanowire layer on the base layer. The nanowire layer comprises at least one vertical nanowire and a supporting material laterally enclosing the at least one vertical nanowire. The method comprises depositing a heterostructure on the nanowire layer and in contact with the at least one vertical nanowire. The method comprises forming at least one source contact in contact with the heterostructure. The method comprises forming a gate contact in contact with the heterostructure. The method comprises forming a drain contact in contact with the at least one vertical nanowire.

The term forming may be understood as forming, by any applicable method, the specified layers and structures. Forming may be understood as e.g. depositing, epitaxially growing, etching, or an integrated lithography-based pattern transfer process to name just a few examples.

The method provides an efficient and low complexity/readily available method to form a vertical HEMT according to the first aspect. Due to this, the same advantages may also apply for the second aspect as for the first aspect.

The substrate may be a silicon substrate. The base layer may comprise an AlN-layer arranged on the substrate.

Silicon substrates are cheap and readily available. Vertical nanowire of lattice mismatched material relative to silicon, e.g. GaN, may be formed directly onto silicon substrates with better resulting material quality than bulk GaN material. The AlN-layer may act as a transition layer between the silicon substrate and the nanowire layer.

The method may further comprise separating the substrate from the AlN-layer. The method may further comprise forming a trench in the AlN-layer. The method may further comprise exposing the at least one vertical nanowire. The step of forming the drain contact may comprise forming the drain contact in the trench.

Such a method may be performed with existing equipment and provides access to form the drain contact beneath the nanowire layer.

The method may further comprise joining the substrate or another substrate to the AlN-layer and/or the drain contact. Once the drain contact is formed, the substrate, or another substrate may be re-joined combined structure. Closer co-integration with devices, structures, and circuitry on the substrate may thus be achieved.

The step of depositing the heterostructure may comprise depositing an AlGaN-layer. The step of depositing the heterostructure may comprise depositing a GaN-layer. The AlGaN-layer and the GaN-layer may together form a heterojunction.

It should be understood that it may not be necessary to rejoin the substrate or another substrate to the AlN-layer and/or the drain contact. Alternatively, the vertical HEMT may be left without a substrate joined to the AlN-layer and/or without a substrate joined to the drain contact. As an example, the vertical HEMT may be left with no substrate. As another example, a substrate with a trench may be joined to the AlN-layer, the trench may be of the same size as the drain contact and align with the drain contact, such that the drain contact is not joined to the substrate. As another example, a substrate with a trench may be joined to the AlN-layer, the trench may be of a similar size as the drain contact, e.g. between 1 and 5 times the size of the drain contact, and align with the drain contact, such that the drain contact, and a surrounding area, is not joined to the substrate. In the above examples the trench in the substrate may be replaced by a hole through the substrate.

The absence of a substrate at the drain contact and/or in a region in the vicinity of the drain contact may improve the operation voltage capabilities of the vertical HEMT. Such a device may potentially be operated above 1000 V. The absence of a substrate at the drain contact and/or in a region in the vicinity of the drain contact may ensure that there are no charge traps at the drain contact and/or in a region in the vicinity of the drain contact. Consequently, it may be ensured that there are no charge traps in the vicinity of the gate contact. Further, the AlN-layer may be a layer of sputtered AlN. Such a layer may further improve the operation voltage capabilities of the vertical HEMT. Sputtered AlN may have fewer charge traps than epitaxially grown AlN.

Generally, all terms used in the claims are to be interpreted according to their ordinary meaning in the technical field, unless explicitly defined otherwise herein. All references to “a/an/the [element, device, component, means, step, etc]” are to be interpreted openly as referring to at least one instance of said element, device, component, means, step, etc., unless explicitly stated otherwise. The steps of any method disclosed herein do not have to be performed in the exact order disclosed, unless explicitly stated.

A further scope of applicability of the present invention will become apparent from the detailed description given below. However, it should be understood that the detailed description and specific examples, while indicating preferred embodiments of the invention, are given by way of illustration only, since various changes and modifications within the scope of the invention will become apparent to those skilled in the art from this detailed description.

Hence, it is to be understood that this invention is not limited to the particular component parts of the device described or acts of the methods described as such device and method may vary. It is also to be understood that the terminology used herein is for purpose of describing particular embodiments only, and is not intended to be limiting.

It must be noted that, as used in the specification and the appended claims, the articles “a,” “an,” “the,” and “said” are intended to mean that there are one or more of the elements unless the context clearly dictates otherwise. Thus, for example, reference to “a unit” or “the unit” may include several devices, and the like. Furthermore, the words “comprising”, “including”, “containing” and similar wordings does not exclude other elements or steps.

### BRIEF DESCRIPTION OF THE DRAWINGS

The above and other aspects of the present invention will, in the following, be described in more detail with reference to appended figures. The figures should not be considered limiting; instead they should be considered for explaining and understanding purposes.

As illustrated in the figures, the sizes of layers and regions may be exaggerated for illustrative purposes and, thus, are provided to illustrate the general structures. Like reference numerals refer to like elements throughout.

FIGS. 1a-b show side views of vertical HEMTs.

FIG. 2 shows a flow chart for methods of producing vertical HEMTs.

### DETAILED DESCRIPTION

The present invention will now be described more fully hereinafter with reference to the accompanying drawings, in which currently preferred embodiments of the invention are shown. This invention may, however, be embodied in many different forms and should not be construed as limited to the embodiments set forth herein; rather, these embodiments are provided for thoroughness and completeness, and to fully convey the scope of the invention to the skilled person.

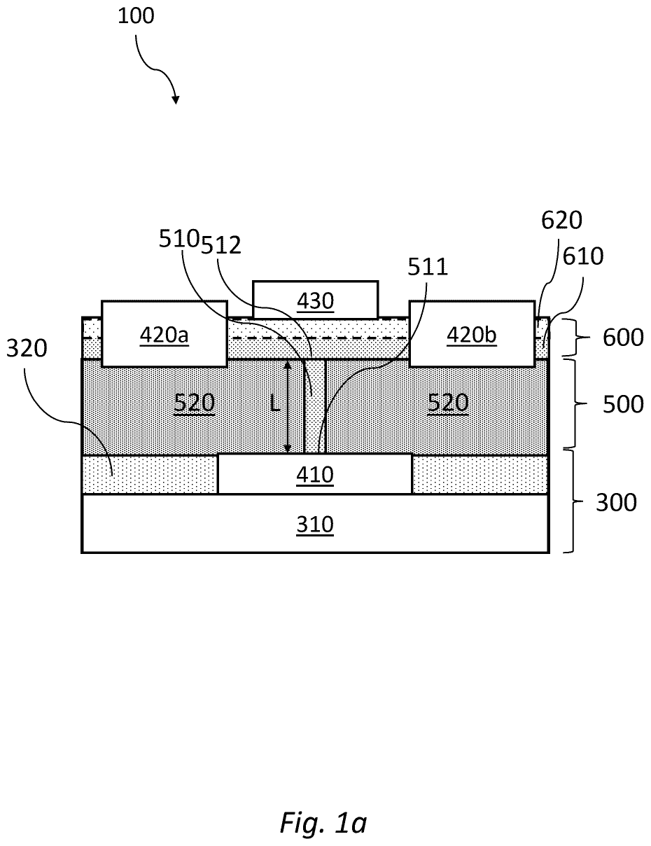

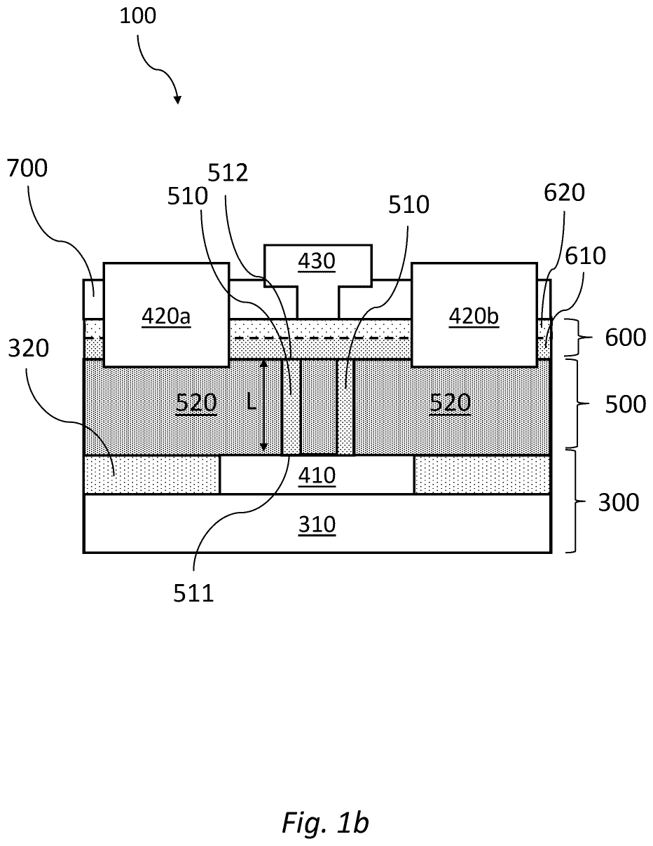

FIG. 1a shows a vertical HEMT 100. The vertical HEMT 100 comprises a drain contact 410.

The drain contact 410 may, as shown, be arranged on a substrate 310. The substrate 310 may be a silicon, Si, substrate. The substrate may have a Miller index of <111>.

The drain contact 410 may also be laterally enclosed by an AlN-layer 320.

The vertical HEMT 100 comprises a nanowire layer 500 arranged on the drain contact 410. The nanowire layer 500 may comprise at least one vertical nanowire 510 and a supporting material 520 lateraly enclosing the at least one vertical nanowire 510.

The at least one vertical nanowire 510 forms an electron transport channel between the drain contact 410 and the heterostructure 600.

The at least one vertical nanowire 510 may comprise a first end 511 and a second end 512 at two opposite vertical boundaries of the vertical nanowire. The first end 511 may be in direct contact with the drain contact 410. The second end 512 may be in direct contact with the heterostructure 600.

The at least one vertical nanowire 510 may be laterally aligned with the gate contact 430 as is shown to be the case in FIG. 1a.

The length, L, of the at least one vertical nanowire 510 may be in the range from 50 nm to 500 nm, and may preferably be in the range from 150 nm to 250 nm.

The at least one vertical nanowire 510 may have a hexagonal or a circular radial cross section. The at least one vertical nanowire 510 may have a diameter in the range from 10 to 500 nm for confinement of the density of states in the radial direction. The diameter of the at least one vertical nanowire 510 may preferably be in the range from 10 to 100 nm. The diameter may be fix along the length of the at least one nanowire 510. The diameter, and indeed also the radial cross section shape, may change along the length of the at least one nanowire 510.

The at least one vertical nanowire 510 may comprise GaN.

The material of the at least one vertical nanowire 510 may be different from the supporting material 520.

The at least one vertical nanowire 510 may comprise n-doped GaN. GaN may be n-doped by doping with C or Si impurity atoms. The supporting material 520 may comprise p-doped GaN. GaN may be p-doped by doping with Mg impurity atoms.

The supporting material 520 may be configured to be a current blocking layer.

The nanowire layer 500 may comprise a plurality of vertical nanowires 510. The plurality of vertical nanowires 510 may be arranged laterally in a square array or a hexagonal array.

The vertical HEMT 100 comprises a heterostructure 600 arranged on the nanowire layer. The heterostructure 600 may comprise an AlGaN-layer 610 and a GaN-layer 620 that together form a heterojunction.

The GaN-layer 620 may be arranged on the AlGaN-layer 610.

The GaN-layer 620 may comprise or substantailly consist of GaN. The AlGaN-layer 610 may comprise or substantailly consist of AlGaN. AlGaN may feature many different elemental composition ratios. In general, AlGaN should be considered to be AlₓGa₁₋ₓN, wherein 0<x<1

The vertical HEMT 100 comprises at least one source contact 420a, 420b in contact with the heterostructure 600. The at least one source contact 420a, 420b should however be laterally offset from the at least one vertical nanowire 510.

The vertical HEMT 100 may comprise a plurality of source contacts 420a, 420b, as shown in FIG. 1a. The shown configuration may alternatively be understood as a setup with multiple source contact fingers 420a, 420b, that are essentially integral and correspond to the same electrical node. The placement of the multiple source contact fingers 420a, 420b laterally equidistant around the center of the at least one vertical nanowire 510, may be preferable for a more even spread throughout the heterostructure 600 and the at least one nanowire 510.

For the same reasons, the source contact 420a, 420b may alternatively be circular in shape, centered around an extended centerline of the at least one vertical nanowire 510.

In cases with a plurality of vertical nanowires 510, the source contact 420a, 420b may be configured as a grid in which substituent grid elements are consistent across the grid in how they correspond to each individual vertical nanowire 510. E.g. the closest distance between any point of a vertical nanowire 510 and any point of the source contact 420a, 420b should preferably be equal for each individual vertical nanowire 510.

The vertical HEMT 100 comprises a gate contact 430 in contact with the heterostructure 600, arranged above the at least one vertical nanowire 510.

The gate contact 430, the at least one source contact 420a, 420b, and the drain contact 410 may comprise or substantially consist of metal material. Examples of metal materials available for use, by themselves or in an alloy/compound, may include Cu, Al, Pd, Au, Ag, Ni, Ti, W.

With reference to FIG. 1a, the vertical HEMT operation may be described as the gate contact 430 receiving a voltage. The voltage may be a positive voltage. If the voltage is large enough, a 2DEG may form at the heterojunction, i.e. the interface between the AlGaN-layer 610 and the GaN-layer 620, and open the transistor for conducting currents between the source contact 420a, 420b and drain contact 410 via the at least one nanowire 510. The path of the current may be along the heterojunction until it approaches the part of the heterojunction closest to the at least one vertical nanowire 510. The current now transits to the at least one vertical nanowire 510 continue flowing toward the drain contact 430. The interfaces between the different structures and layers in the currents path may be optimized to feature substantially ohmic conduction across each interface.

FIG. 1b shows a slightly altered version of the vertical HEMT 100 that also includes a top oxide-layer 700. Such an oxide-layer 700 may beneficially reduce current leakage between e.g. the gate contact 430 and the source contacts 420a, 420b and better insulate and passivate the vertikal HEMT.

FIG. 1b also shows an example of the nanowire layer 500 comprising a plurality of vertical nanowires 510. In the figure two similar nanowires are shown in parallel with each other. In this case the gate contact 430 aligned with a central point between the two vertical nanowires 510 instead of the at least one vertical nanowire as is shown in FIG. 1a.

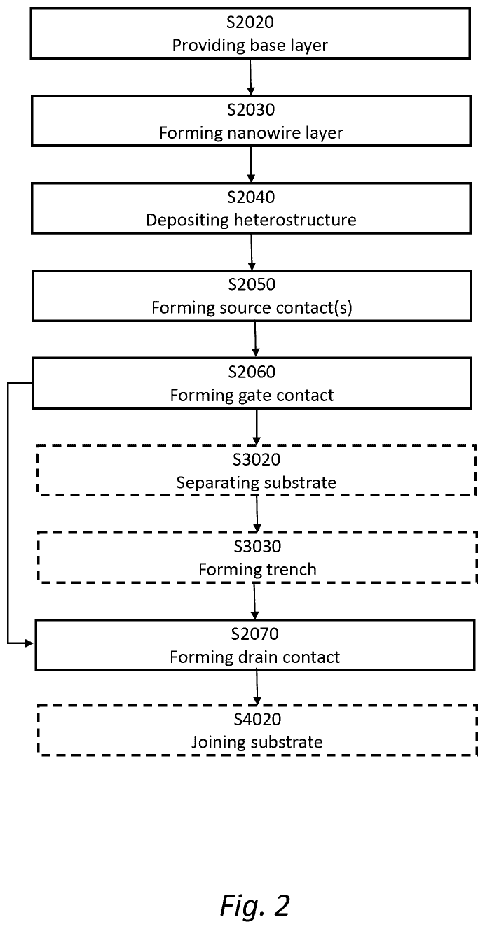

FIG. 2 shows a flowchart for a method of producing a vertical HEMT 100. Optional steps are indicated by dashed boxes in the flowchart.

The method comprises providing S2020 a base layer 300 wherein the base layer 300 comprises a substrate 310.

The substrate 310 may be a silicon substrate. The base layer 300 may comprise an AlN-layer 320 arranged on the substrate 310. The AlN-layer 320 may be formed by a suitable deposition technique, e.g. sputtering or chemical vapor deposition, CVD, onto the substrate 310. Sputtered AlN may be advantageous as it may provide a low density of charge traps, e.g. a low density of charge traps at the interface between the AlN-layer 320 and a substrate.

The method comprises forming S2030 a nanowire layer 500 on the base layer 300. The nanowire layer 500 comprises at least one vertical nanowire 510 and a supporting material 520 laterally enclosing the at least one vertical nanowire 510.

The at least one vertical nanowire 510 may be formed by selective area growth epitixal techniques, e.g. using metal organic vapor phase epitaxy, MOVPE, or by selectively etching out the vertical nanowire 510 from a bulk layer of semiconductor material e.g. by plasma etching using chloride chemistry Ar/Cl. The step of forming the at least one vertical nanowire 510 may comprise using lithography-based pattern transfer techniques to define the intended position and geometry of the at least one nanowire 510.

The supporting material 520 may be formed by deposition techniques such as e.g. MOVPE or CVD to enclose the at least one vertical nanowire 510 or fill in the space between nanowires 510 if a plurality of them are present.

The method comprises depositing S2040 a heterostructure 600 on the nanowire layer 500 and in contact with the at least one vertical nanowire 510.

The heterostructure 600 may be deposited by similar techniqes to the at least one vertical nanowire 510, i.e. MOVPE.

The step of depositing S2040 the heterostructure 600 may comprise depositing an AlGaN-layer 610, and depositing a GaN-layer 620. The AlGaN-layer 610 and the GaN-layer 620 may together form a heterojunction.

The first layer of the heterostructure 600, e.g. the AlGaN-layer 610, may be deposited onto the nanowire layer 500. The second layer of the heterostructure, in that case the GaN-layer 620, may then be deposited onto the AlGaN-layer 610.

The method comprises forming S2050 at least one source contact 420a, 420b in contact with the heterostructure 600.

The source contact 420a, 420b may be formed by depositing techniques such as evaporation or sputtering. The source contact 420a, 420b may, as shown in FIG. 1a, be formed vertically through the heterostructure 600, and onto the nanowire layer 500. This result may be achieved by pattern transfer and selective area etching through the heterostructure before deposition of the source contact 420a, 420b.

The method comprises forming S2060 a gate contact 430 in contact with the heterostructure. The gate contact 430 may be formed using deposition techniques similar to those suggested for the source contact 410a, 410b. The gate contact 430 may be formed onto the heterostructure 600 as shown in FIG. 1a. In FIG. 1b, where the oxide-layer 700 is present, etchning may first be used to create a trench for the gate contact 430 through the oxide-layer.

The method may further comprise separating S3020 the substrate 310 from the AlN-layer 320 using substrate removal or separation techniques.

The method may further comprise forming S3030 a trench in the AlN-layer 320, exposing the at least one vertical nanowire 510. The step of forming the drain contact 410 may in this case comprise forming the drain contact 410 in the trench. The trench may act as a mold for the drain contact 410. As such, the trench shares its geometry with the drain contact 410 in FIGS. 1a-b.

The trench may be formed by selective area etching, from below as seen in the figures, through the AlN-layer 320 to.

The method comprises forming S2070 a drain contact 410 in contact with the at least one vertical nanowire 510. The drain contact 410 may be formed using deposition techniques similar to those suggested for the source contact 410a, 410b and gate contact 430.

The forming of the drain contact 410 may also comprise preceeding etching, from the bottom and through, the substrate 310. Trenches may be selectively etched through an oxide-layer of the substrate bottom surface. The remaining bottom substrate oxide-layer may then be used as a mask layer for dry reactive ion etching of the substrate 310.

The method may further comprise joining S4020 the substrate 310 or another substrate to the AlN-layer 320 and/or the drain contact 410. The joinging step S4020 may entail joining a previously used substrate 310, separated from the rest of the structure in step S3020, or it may entail joining an entirely different substrate. If precise alignement is desired in joining, automated stepper equipment may be employed to aid during step. The joinging step S4020 may entail joining a substrate with a trench to the AlN-layer. The trench may be of the same size as the drain contact 410 and align with the drain contact 410. Thus, the substrate may be joined to the AlN-layer but not to the drain contact 410, as the trench in the substrate may prevent contact between the substrate and the drain contact 410. Alternatively, the trench may be of a similar size as the drain contact 410, e.g. between 1 and 5 times the size of the drain contact 410, and align with the drain contact 410. Thus, the substrate may be joined to the AlN-layer but not to the AlN-layer in a region around the drain contact 410.

Additionally, variations to the disclosed embodiments can be understood and effected by the skilled person in practicing the claimed invention, from a study of the drawings, the disclosure, and the appended claims.

What is claimed is:

1. A vertical transistor, comprising:
a drain contact;
a vertical electron transport layer arranged on the drain contact, the vertical electron transport layer comprising:
a vertically conducting aperture, and
a supporting material laterally enclosing or defining the vertically conducting aperture, the supporting material is configured to be a current blocking layer;
a heterostructure arranged on the vertical electron transport layer and comprising an AlGaN-layer and a GaN-layer together forming a heterojunction;
at least one source contact in contact with the heterostructure, the at least one source contact being laterally offset from the vertically conducting aperture; and
a gate contact in contact with the heterostructure, arranged above the vertically conducting aperture,
wherein the vertically conducting aperture is forming an electron transport channel between the drain contact and the heterostructure.

2. The vertical transistor according to claim 1, wherein the vertically conducting aperture at a first end thereof is in direct contact with the drain contact and at a second end thereof is in direct contact with the heterostructure.

3. The vertical transistor according to claim 1, wherein the material of the at vertically conducting aperture is different from the supporting material.

4. The vertical transistor according to claim 3, wherein the vertically conducting aperture comprises n-doped GaN and wherein the supporting material comprises p-doped GaN.

5. The vertical transistor according to claim 1, wherein the drain contact is laterally enclosed by an AlN-layer, and wherein the vertical electron transport layer is arranged on the drain contact and on the AlN-layer laterally enclosing the drain contact.

6. The vertical transistor according to claim 1, wherein the vertically conducting aperture is laterally aligned with the gate contact.

7. The vertical transistor according to claim 1, wherein a vertical extension of the vertically conducting aperture is in the range from 50 nm to 500 nm.

8. The vertical transistor according to claim 1, further comprising an oxide-layer arranged ontop of the heterostructure, wherein the at least one source contact is penetrating the oxide-layer and being in contact with the heterostructure, and wherein the gate contact is penetrating the oxide-layer and being in contact with the heterostructure.

9. The vertical transistor according to claim 1, wherein vertical electron transport layer is arranged on a base layer comprising a gallium nitride substrate.

10. A method for producing a vertical transistor, the method comprising:
providing a base layer wherein the base layer comprises a substrate;
forming a vertical electron transport layer on the base layer, the vertical electron transport layer comprises a vertically conducting aperture and a supporting material laterally enclosing or defining the vertically conducting aperture, the supporting material is configured to be a current blocking layer, wherein the forming of the vertical electron transport layer comprises:
epitaxially forming the vertically conducting aperture, and
depositing the supporting material after formation of the vertically conducting aperture;
depositing a heterostructure on the vertical electron transport layer and in contact with the vertically conducting aperture, the heterostructure comprising an AlGaN-layer and a GaN-layer together forming a heterojunction;
forming at least one source contact in contact with the heterostructure, the at least one source contact being laterally offset from the vertically conducting aperture;
forming a gate contact in contact with the heterostructure and arranged above the vertically conducting aperture; and
forming a drain contact in contact with the vertically conducting aperture;
wherein the vertically conducting aperture is forming an electron transport channel between the drain contact and the heterostructure.

11. The method according to claim 10, wherein the substrate is a silicon substrate, and wherein the base layer comprises an AlN-layer arranged on the substrate.

12. The method according to claim 11, wherein the method further comprises:
separating the substrate from the AlN-layer,
forming a trench in the AlN-layer, exposing the vertically conducting aperture, and
wherein the step of forming the drain contact comprises:
forming the drain contact in the trench.

13. The method according to claim 10, further comprising depositing an oxide layer on the heterostructure, wherein forming the at least one source contact and forming the gate contact both comprises creating a respective trench through the oxide-layer.
